(19) United States
(12) Patent Application Publication
(10) Pub. No.: US 2009/0303776 A1
(43) Pub. Date: Dec. 10, 2009

(54) STATIC RANDOM ACCESS MEMORY CELL

(75) Inventor: Hugh T. MAIR, Fairview, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/436,204

(22) Filed: May 6, 2009

Related U.S. Application Data
(60) Provisional application No. 61/059,206, filed on Jun. 5, 2008.

(51) Int. Cl. G11C 11/00; G11C 7/00; G11C 5/14

(52) U.S. Cl. 365/154; 365/189.05; 365/226

(57) ABSTRACT

A six transistor (“6T) static random access memory (“SRAM”) cell and method for using the same are disclosed herein. The 6T SRAM cell includes a single read pass gate transistor and a single write pass gate transistor. The single read pass gate transistor is connected to a read bit line and a read word line. The single write pass gate transistor connected to a write bit line and a write word line.

The present application claims priority to and incorporates by reference provisional patent application 61/059,206, filed on Jun. 5, 2008, entitled “6T Ram Cell and Operation At Ultra-Low Voltage.”

### BACKGROUND

The six-transistor (“6T”) static random access memory (“SRAM”) cell is used in numerous data storage applications. 6T SRAM cells are especially advantageous in applications where reduced power consumption is desirable, because the static power dissipation of the cell can be very low.

A conventional 6T SRAM cell can be formed with pair of cross-coupled inverters. Each inverter includes a p-channel transistor and an n-channel transistor. The source of a first pass gate transistor is connected to the gate nodes of the first inverter and the drain nodes of the second inverter. Similarly, the source of a second pass gate transistor, is connected the gate nodes of the second inverter and the drain nodes of the first inverter. The gates of the pass gate transistors are connected to a common word line, and the drains of the pass gate transistors are connected to a differential bit line.

The conventional cell is read and written by driving the word line and differential bit line to various states. For example, the cell may be read by pre-charging the differential bit line (both positive and negative signals) to a common voltage and asserting the word line to active the pass gate transistors. Similarly, the cell may be written by differentially driving the bit lines and asserting the word line to active the pass gate transistors.

To reduce device power consumption, it is often beneficial to operate a device at a reduced power supply voltage. Unfortunately, conventional 6T SRAM cells encounter various problems, for example read and/or write disturb problems, when operated at ultra-low voltages. To overcome these problems, various cell designs incorporating seven or more transistors have been proposed. Such designs generally result in an increase in device area and/or power consumption.

### SUMMARY

A six transistor (“6T) static random access memory (“SRAM”) cell having improved low voltage stability and a method for using the cell are disclosed herein. In accordance with at least some embodiments, a 6T SRAM cell includes a single read pass gate transistor and a single write pass gate transistor. The single read pass gate transistor is connected to a read bit line and a read word line. The single write pass gate transistor connected to a write bit line and a write word line.

In accordance with at least some other embodiments, a method includes reading a six transistor (“6T”) static random access memory (“SRAM”) cell and writing the 6T SRAM cell by: negating a write word line connected to the cell and asserting a read word line connected to the cell. Asserting the read word line activates a single read pass gate transistor in the cell and causes the cell to provide a latched value on a single-ended read bit line connected to the cell.

In accordance with yet other embodiments, a memory array includes a plurality of 6T SRAM cells. Each SRAM cell is connected to a single read word line and a single write word line. A value is written into each of the plurality of SRAM cells when the single write word line is asserted.

### BRIEF DESCRIPTION OF THE DRAWINGS

For a detailed description of exemplary embodiments of the invention, reference will now be made to the accompanying drawings in which:

FIG. 1 shows a six transistor (“6T”) static random access memory (“SRAM”) cell in accordance with various embodiments;

FIG. 2 shows a 6T SRAM cell array in accordance with various embodiments; and

FIG. 3 shows a flow diagram for a method for operating a 6T SRAM cell in accordance with various embodiments.

### NOTATION AND NOMENCLATURE

Certain terms are used throughout the following description and claims to refer to particular system components. As one skilled in the art will appreciate, computer companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect, direct, optical or wireless electrical connection. Thus, if a first device couples to a second device, that connection may be through a direct electrical connection, through an indirect electrical connection via other devices and connections, through an optical electrical connection, or through a wireless electrical connection.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Disclosed herein are a novel six transistor (“6T”) static random access memory (“SRAM”) cell and a method of operating the cell. As feature sizes and power supply voltages are reduced, conventional 6T SRAM cells become more susceptible to unintended changes in value caused by accesses to other cells (i.e., read or write disturb) due to reduced static noise margin and increased device variability (e.g., threshold variance). Schemes that add transistors to the SRAM to avoid these instabilities often have other undesirable consequences. Embodiments of the present disclosure overcome the deficiencies of the conventional 6T SRAM cell by allowing independent optimization of cell read and/or write device parameters.

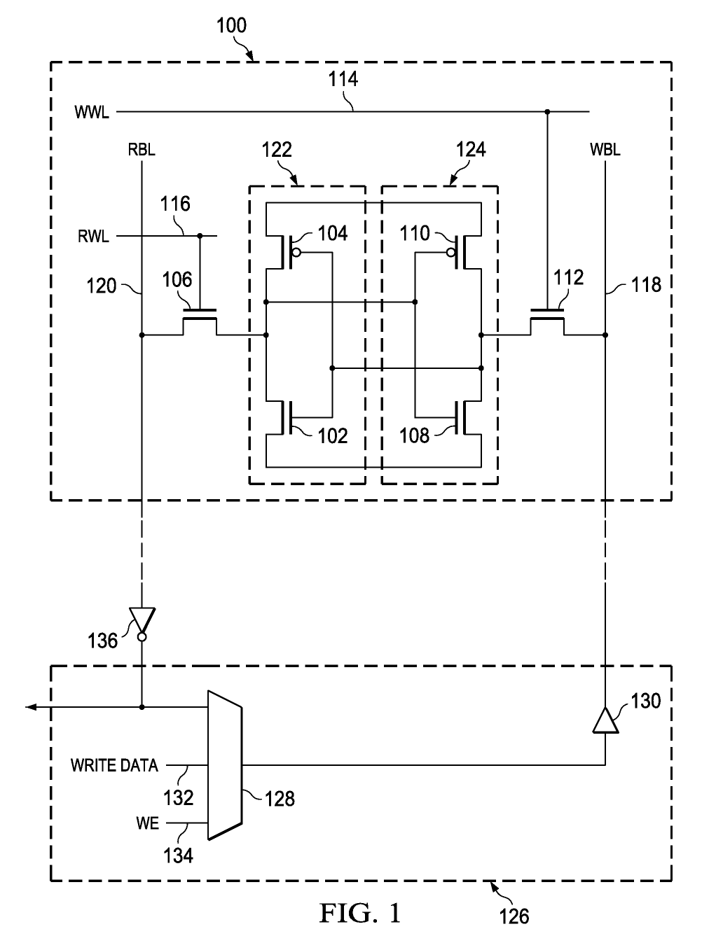

FIG. 1 shows a 6T SRAM cell 100 in accordance with various embodiments. The cell 100 includes a pair of inverters 122, 124. The inverters 122, 124 are cross-coupled (i.e., the output of one connects to the input of the other) to form a latch that serves as the cell 100 storage element. The read side inverter 122 includes a p-type (“load”) transistor 104 coupled to an n-type (“driver”) transistor 102. Similarly, the write side inverter 124 includes a p-type transistor 110 coupled to an n-type transistor 108.

The cell includes a pair of n-type pass gate transistors 106, 112. The read pass gate transistor 106 is coupled to the read side inverter 122, and the write pass gate transistor 112 is coupled to the write side inverter 124. A read word line 116 is connected to the gate of the read pass gate transistor 106. Assertion of the read word line 116 allows the value present on the output of the read side inverter 122 to be driven onto the read bit line 120 via the read pass gate transistor 106. A write word line 114 is connected to the gate of the write pass gate transistor 112. Assertion of the write word line 114 activates the write pass gate transistor 112, and allows the value present on the write bit line 118 to be driven into, and retained by the latch formed the inverters 122, 124.

As shown, in the cell 100, the write word line 114 is separate from the read word line 116, and the read bit line 120 is separate from the write bit line 118. The read bit line 120 and the write bit line 118 are single-ended. By separating the read control features (e.g., read pass gate 106, read word line 116, and read bit line 120) from the write control features (e.g., write pass gate 112, write word line 114, and write bit line 118) embodiments of the present disclosure allow for the read side transistors 102, 104, 106 to be optimized independently of the write side transistor 108, 110, 112. In an embodiment employing a single differential bit line, and a single word line controlling both pass gates, the pass gate parameters should be substantially identical, and the parameters of one inverter's transistors should be substantially identical to those of the respective transistors of the other inverter to provide proper control of the cell. Thus, such embodiments do not allow for independent optimization of read and write parameters, and control of the cell's parameters becomes increasingly difficult with reduced power supply voltage and/or feature sizes.

By allowing independent optimization of read and write side transistor parameters, embodiments of the present disclosure provide improved resistance to read and write disturb without increasing cell transistor count. Thus, embodiments allow for power supply and feature size reductions with compensation for process variability.

A read disturb event occurs when a read access of the cell 100 causes the value stored in the cell 100 latch to change. Such a change can occur when current flowing from the read bit line 120 into the cell 100, through the read pass gate transistor 106, overcomes the read side inverter 122 driver transistor 102 to the degree that the write side inverter 124 input threshold is exceeded, causing the latched value to change. Some embodiments of the present disclosure improve the read disturb characteristics of the cell 100 by adjusting the parameters of either the read pass gate transistor 106 or the read side inverter 122 driver transistor 102 with respect to the other transistor 102, 106. In such embodiments, the read pass gate transistor 106 may be weakened with respect to driver transistor 102, or the driver transistor 102 may be strengthened with respect to the read pass gate transistor 106. Either adjustment aids in overcoming read disturb based disruption of the cell 100 by reducing the likelihood that current flowing into the cell 100 from the read bit line 120 will overcome the driver transistor 102 and cause the value latched in the cell 100 to change. Weakening the read pass gate transistor 106 advantageously allows the size of the transistor 106 to be reduced. No changes to the parameters of the write side inverter 124, the write side pass gate transistor 112, or the read side inverter load transistor 104 are required to improve read disturb performance and none are required as a result of changes to the read side pass gate transistor 106 or the read side inverter driver transistor 102.

In conventional embodiments of a 6T SRAM cell, a write disturb event occurs when a cell not being written shares a word line with a cell that is being written and current flowing from the bit line into the cell causes the latch to change state. Embodiments of the present disclosure eliminate write disturb issues by writing every cell 100 connected to the write word line 114. When any cell 100 connected to the write word line 114 is to be written, all the cells connected to the write word line are read. The output of the read sense circuit 136 connected to the read bit line 120 is provided to a multiplexer 128. A write data value 132 to be written to a cell 100 is also provided to the multiplexer 128. If the cell 100 connected to the write word line 114 and the write bit line 118 is not to be written, then the write enable 134 signal causes the multiplexer 128 to select the output of the read sense circuit 136, otherwise the write data value 132 is selected as the multiplexer 128 output. The multiplexer 128 output is provided to a write bit line driver 130, and written into the cell 100 when the write word line 114 is asserted. Thus, a read-modify-write operation is performed as to all cells on a write word line 114, and consequently, write disturb is eliminated.

In at least some embodiments, cell 100 write operations are enhanced by decreasing the resistance of the write pass gate transistor 112 that connects the write bit line 118 to the cell latch. In some embodiments, the resistance is decreased by increasing the write word line 114 voltage to turn the write pass gate transistor 112 on harder. In some embodiments, the current flowing through the write pass gate transistor 112 is increased by increasing the voltage on the write bit line 118. In such embodiments, the write bit line driver 130 may be configured to drive the write bit line to a high voltage (i.e., higher than cell 100 power supply voltage). In at least some embodiments, the write word line 114 and/or the write bit line 118 can be driven to a voltage higher than the voltage applied to the sources of the inverter load transistors 104, 110.

Thus, embodiments of the present disclosure allow for optimization of read margin without effect on write margin, and optimization of write margin without effect on read margin.

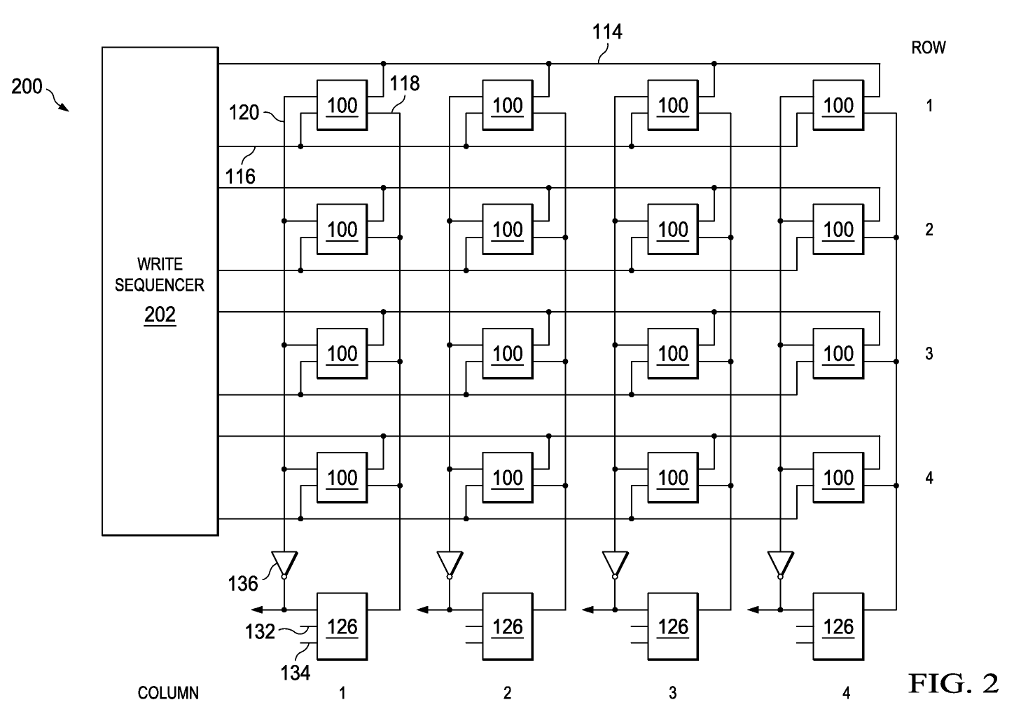

FIG. 2 shows a 6T SRAM cell array 200 in accordance with various embodiments. The array 200 includes a plurality of 6T RAM cells 100 arranged as rows and columns. Each cell 100 in a row is connected to the same write word line and read word line. For example, each of the cells 100 in row 1 is connected to the write word line 114 and the read word line 116. Each cell in a column is connected to the same write bit line and read bit line. For example, each cell 100 in column 1 is connected to the write bit line 118 and to the read bit line 120. Each column further includes write multiplexing logic 126 that provides one of a value present on the read bit line and a write data value to the write bit line during an array write cycle. Because the multiplexing logic 126 is applied on a column basis, areal overhead is kept low.

Also shown in FIG. 2 is an array write sequencer 202. The array write sequencer 202 controls the array read-modify-write operation performed on each array write cycle. When a cell 100 is to be written, the write sequencer causes the read word line associated with a row having a cell to be written to be asserted prior to the assertion of the write word line. This pre-read drives the read bit lines to values contained in the cells, and the pre-read values can then be fed back to the cells based on the write enable input to the multiplexer logic for each column.

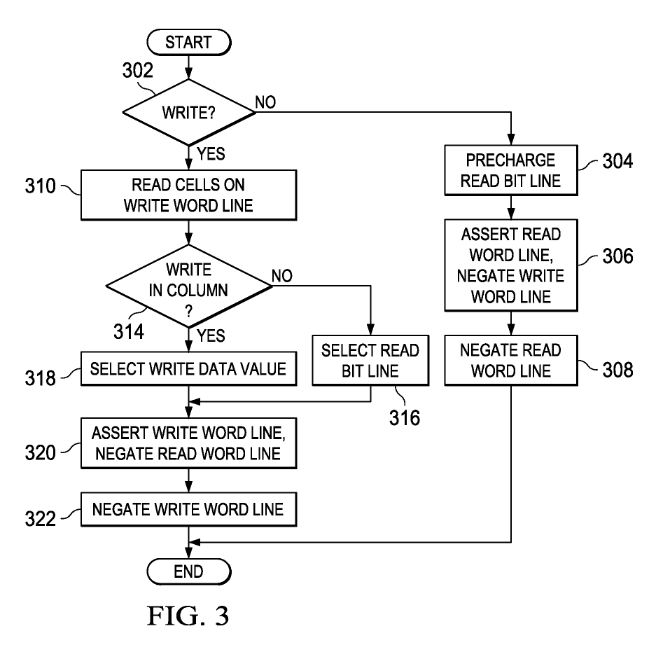

FIG. 3 shows a flow diagram for a method for operating a 6T SRAM cell in accordance with various embodiments. Though depicted sequentially as a matter of convenience, at least some of the actions shown can be performed in a different order and/or performed in parallel. Additionally, some embodiments may perform only some of the actions shown.

In block 302, whether the cell 100 is to be read or written is determined. If the cell 100 is to be read, then, in block 304, the read bit line 120 is pre-charged. In some embodiments, the read bit line is charged to the voltage level applied to the source terminals of inverter load transistors 104 and 110. Having pre-charged the read bit line 120, the read word line 116 is asserted, and the write word line 118 is negated. Generally, prior to cell 100 access, both the read word line 120 and the write word line 118 are negated. Asserting the read word line 116 allows current to flow through the read pass gate transistor 106. If the output of the inverter 122 is low, the read bit line 120 will be pulled low through the read pass gate transistor 106. If the output of the inverter 122 is high, the read bit line 120 will not be pulled down, but will remain at a voltage level provided by the pre-charge. The read sense circuit 136 detects the read bit line 120 voltage and provides the cell 100 output to other circuits. In block 308, the read word line 116 is negated to complete the cell 100 read operation.

If, in block 302, a write to the cell 100 is initiated, then a read cycle is performed prior to the write cycle. As explained above, embodiments of the cell 100 employ a single ended read bit line 120, and a single ended write bit line 118. The single ended write bit line 118 indicates that each of multiple cells connected to the write word line 114 are written when the write word line 114 is asserted. To provide for changing only a value stored in a selected cell 100 connected to the word line 118, and to improve the write disturb immunity of the cell 100, read-modify-write operation is employed. Accordingly, in block 310, each cell 100 connected to the write word line 114 is read. The cells 100 can be read by performing the operations explained with regard to blocks 304, 306, and 308.

In block 314, whether the write is applicable to a given column (i.e., a particular write bit line) is determined. If write data (i.e., new data) is to be written to a cell 100 in the given column, then, in block 318, the multiplexer 128 selects the write data value 132 to be driven onto the write bit line 118. If the data stored in the cells of the given column is to remain unchanged, then, in block 316, the multiplexer 128 selects the value read from the cell 100 onto the read bit line 120 to be driven onto the write bit line 118.

In block 320, the write word line 114 is asserted, and the read word line 116 is negated. Asserting the write word line 114 causes the write pass gate transistor 112 to turn on, thus providing the value present on the write bit line 110 to the inverters 122, 124 of the cell 100. In at least some embodiments, the write word line 114 is driven to a higher voltage than the power supply voltage applied to the inverter 124 transistor 110 (i.e., a high voltage). Driving the write word line 114 to a high voltage reduces the resistance of the write pass gate transistor 112, and allows the write pass gate transistor 112 to more readily overcome the transistors 108, 110 of the write side inverter 124. In some embodiments, the write bit line 118 can be driven to a high voltage to provide increased current flow through the write pass gate transistor 112. In some embodiments, only a write bit line 118 driven with a write data value 132 may be driven to a high voltage. The write cycle is completed with negation of the write word line 114 in block 322.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A six transistor (“6T”) static random access memory (“SRAM”) cell, comprising:
a single read pass gate transistor connected to a read bit line and a read word line; and
a single write pass gate transistor connected to a write bit line and a write word line.

2. The 6T SRAM cell of claim 1, wherein the read bit line and the write bit line are single-ended.

3. The 6T SRAM cell of claim 1, further comprising:
a first inverter and a second inverter, each inverter comprising an N-type device and a P-type device, the first and second inverters are cross-coupled to form a latch;
wherein the read pass gate transistor connects the read bit line to an output of the first inverter and a control input of the second inverter, and the write pass gate transistor connects the write bit line to an output of the second inverter and a control input of the first inverter;
wherein the read pass gate transistor is configured to provide insufficient current to overcome the output of the P-type device of the first inverter.

4. The 6T SRAM cell of claim 1, wherein the cell is configured to drive a latched value through the read pass transistor and onto the read bit line when the read word line is asserted.

5. The 6T SRAM cell of claim 1, wherein the cell is configured to store a value present on the write bit line when the write word line is asserted.

6. The 6T SRAM cell of claim 1, wherein the cell is configured to perform a cell write cycle by executing a cell read operation followed by a cell write operation.

7. The 6T SRAM cell of claim 1, wherein a voltage applied to the write word line during a write cycle is higher than a voltage applied to a source terminal of a cell latch P-type device.

8. The 6T SRAM cell of claim 1, wherein a drive capability of the read pass gate transistor is determined relative to a drive capability of a load transistor of a read side inverter and without regard for a drive capability of a driver transistor of the read side inverter.

9. The 6T SRAM cell of claim 1, wherein a voltage applied to the write bit line during a write cycle is higher than a voltage applied to a source terminal of a cell latch P-type device.

10. A method, comprising:
reading a six transistor (“6T”) static random access memory (“SRAM”) cell and writing the 6T SRAM cell by:
negating a write word line and asserting a read word line connected to the cell to activate a single read pass gate transistor in the cell and cause the cell to provide a latched value on a single-ended read bit line connected to the cell.

11. The method of claim 10, further comprising selecting one of the value on the read bit line and a cell write data value to drive onto a single-ended write bit line connected to the cell, the selecting is based on a write control signal that indicates whether the cell is to be written.

12. The method of claim 10, further comprising writing a value into every cell connected to write a word line whenever any cell connected to the write word line is written.

13. The method of claim 10, further comprising asserting a write word line and negating a read word line connected to the RAM cell to cause a value on a single-ended write bit line to be written into the RAM cell.

14. The method of claim 10, further comprising driving, during a cell write cycle, at least one of the write word line and a single ended write bit line to a voltage that is higher than a cell power supply voltage.

15. A memory array, comprising:
a plurality of six transistor (“6T”) static random access memory (“SRAM”) cells, each SRAM cell is connected to a single read word line and a single write word line;
wherein a value is written into each of the plurality of SRAM cells when the single write word line is asserted.

16. The memory array of claim 15, further comprising a write sequencer that controls SRAM array write accesses, wherein the sequencer causes each of the plurality of SRAM cells connected to the write word line to be read prior to writing any of the plurality of cells connected to the write word line.

17. The memory array of claim 15, wherein the plurality of SRAM cells are arranged to form a row of the array, and a plurality of rows are arranged to form a plurality of columns, and each column of the array comprises a multiplexer coupled between a single-ended read bit line connected to each SRAM cell of the column and a single-ended write bit line connected to each SRAM cell of the column.

18. The memory array of claim 17, wherein each multiplexer selects one of a value on the single-ended read bit line and a write data value, the multiplexer output is driven onto the column single-ended write bit line, the selection is based on whether the write data value is to be written to an SRAM cell in the column.

19. The memory array of claim 15, further comprising a driver configured to drive a single-ended write bit line to a voltage that is higher than a power supply voltage applied to the cells.

20. The memory array of claim 15, wherein, during a write cycle, the write word line is driven to a voltage that is higher than a power supply voltage applied to the cells.
